(19) United States
(12) Patent Application Publication
(10) Pub. No.: US 2009/0230447 A1
(43) Pub. Date: Sep. 17, 2009

(54) Semiconductor Device and Method for Manufacturing the Same

(75) Inventor: Sang Min Hwang, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,739

(22) Filed: Jun. 27, 2008

(30) Foreign Application Priority Data
Mar. 13, 2008 (KR) 10-2008-0023546

(51) Int. Cl. H01L 27/108; H01L 29/94; H01L 21/8242; H01L 21/02

(52) U.S. Cl. 257/296; 438/239; 438/394; 257/E21.008; 257/E29.345; 257/E27.084; 257/E21.646

(57) ABSTRACT

A semiconductor device may include a capacitor and a transistor on a silicon-on-insulator (SOI) substrate and a method for manufacturing the semiconductor device may include forming such a structure. A semiconductor device, formed on a silicon-on-insulator structure including first and second silicon layers and a insulating layer buried between the first and the second silicon layers, may include a capacitor including one electrode formed in a doped region of the first silicon layer and the other electrode formed in a well region of the second silicon layer.

### CROSS-REFERENCE TO RELATED APPLICATION

Priority to Korean patent application number 10-2008-23546, filed on Mar. 13, 2008, which is incorporated by reference in its entirety, is claimed.

### BACKGROUND OF THE INVENTION

The present invention generally relates to a semiconductor device and a method for manufacturing the same, and more specifically, to a semiconductor device that requires a capacitor using a Silicon On Insulator (SOI) substrate.

Generally, a semiconductor device is integrated over a silicon wafer. In a silicon wafer used in a semiconductor device, not all of the silicon layer but a limited region of several μm from its top surface is used while the semiconductor device operates. However, the remaining portion except for the limited region of a predetermined thickness from the top surface of the silicon wafer unnecessarily consumes power in operation of the semiconductor device. Accordingly, total power consumption of the semiconductor device is increased and, particularly, an operating speed of the semiconductor device is degraded.

In order to overcome the above-described shortcomings of the silicon wafer, a SOI wafer which includes an insulating layer and a silicon crystalline layer of several μm over a silicon substrate has been suggested. In comparison with semiconductor devices formed over a conventional silicon wafer, it has been reported that semiconductor devices formed over the SOI wafer can operate at higher speed and in a lower voltage condition.

Hereinafter, a conventional semiconductor device formed over the SOI wafer is described.

The semiconductor device formed over the SOI wafer includes a SOI substrate, including a lower silicon substrate in the bottom, an upper silicon layer over which a gate is formed, and an oxide layer formed between the lower silicon substrate and the upper silicon layer. A transistor having a gate is formed over the SOI substrate and a source/drain located in the substrate at both sides of the gate. Generally, the gate has a stacked structure including a gate insulating film, a gate conductive film, and a hard mask film. A spacer is formed on both sidewalls of the gate.

A floating body (FB) transistor which has a floating body surrounded with a source, a drain, and a buried oxide layer of the SOI substrate, stores holes resulting from generation of hot carriers as charges corresponding to transmitted data into the floating body. That is, the FB transistor may have a MOS capacitor function of storing charges as well as a MOS transistor function of switching flow of electricity. When the FB transistor is used in a unit cell of a semiconductor memory device, the FB transistor can store and transmit data without an additional capacitor that has been required to store data in a unit cell of a DRAM. As a result, it is likely that the size of the unit cell of the semiconductor memory device will be reduced to 6F2 and 4F2.

Since a DRAM performs a refresh operation periodically and although the amount of holes that can be stored in the floating body is not large, the FB transistor can be used in DRAM in order to improve integration of the DRAM. However, flow of electricity controlled by the FB transistor is not sufficient for high speed operation. Thus, if the FB transistor is employed in semiconductor devices such as an application-specific integrated circuit (ASIC) or a merged memory logic (MML) circuit that operate both under a low voltage and at high speed, performance of the device cannot be guaranteed at high speed without an additional capacitor for removing a noise occurring at at high speed operation.

A recently proposed a semiconductor device includes a MOS capacitor because it is easy to fabricate the device with large capacitance in a small area. The MOS capacitor employed into a high-integrated semiconductor device can be coupled to a power line supplying a different level depending on its usage. Further, for having sufficient capacitance, the MOS capacitor has a different thickness of a gate oxide film depending on a different power level. For example, in case of the capacitor attached to a power source using a high voltage, the thickness of the gate oxide film in the MOS capacitor is formed to be thicker than that in a general MOS capacitor.

However, it is hard and complicated to adjust a thickness of a gate oxide film corresponding to a different level supplied from power supplies depending on a usage of the MOS capacitor. As a result, it is difficult to secure reliability where gate oxide films formed through a complicated process have different thicknesses.

Also, if some MOS capacitors in the semiconductor device are fabricated depending on different power levels, each MOS capacitor must be decoupled sufficiently from each other and each power source. For this sufficient decoupling, i.e., securing a distance between each neighboring MOS capacitor, a large area is required. However, as a design rule is decreased for increase net dies, there is a limit in broadening the area of each semiconductor device.

### BRIEF SUMMARY OF THE INVENTION

Various embodiments of the present invention are directed at providing a semiconductor device and a method for manufacturing the same that includes forming a contact connected to a well in a lower silicon layer of a SOI wafer and ion-implanting impurities of high concentration into a upper silicon layer of the SOI wafer. The well in the lower silicon layer is used as a bottom electrode, and the upper silicon layer implanted with impurities is used as a top electrode.

According to an embodiment of the present invention, a semiconductor device formed on a silicon-on-insulator structure including first and second silicon layers and a insulating layer buried between the first and the second silicon layers may include a capacitor including one electrode formed in a doped region of the first silicon layer and the other electrode formed in a well region of the second silicon layer.

The semiconductor device further may include a transistor including a gate formed on an active region of the first silicon layer and a source and a drain formed at both sides of the gate in the active region. The semiconductor device may include an isolation layer, formed in a trench where the first silicon layer is removed, for defining the active region.

The semiconductor device further may include: a first contact for coupling the one electrode to a wire; and a second contact having a slit-type shape for coupling the other electrode to another wire. The semiconductor device further may include a plug, formed in the well region, for reducing a contact resistance between the other electrode and the second contact.

The well region may be P type ion-doped, the plug may be P+ type ion-doped, and the doped region may be N+ type ion-doped. The well region may be N type ion-doped, the plug may be N+ type ion-doped, and the doped region may be P+ type ion-doped.

A method for manufacturing a semiconductor device may include: preparing a wafer having a silicon-on-insulator structure including first and second silicon layers and a insulating layer buried between the first and the second silicon layers, wherein the second silicon layer includes a well region as a first electrode of a capacitor; and performing ion-implantation to the first silicon layer to form a second electrode of the capacitor.

The method further may include forming an isolation layer for defining the active region in a trench where the first silicon layer is removed. Also, the method further may include: forming a gate on the active region; and performing an ion-implantation to form a drain and a source at sides of the gate in the active region.

The method further may include: forming an intervening insulation layer over the first silicon layer; forming a first contact on the well region of the second silicon layer through the intervening insulation layer and the insulating layer; and forming a second contact on the second electrode through the intervening insulation layer.

The forming a first contact may include: etching the intervening insulation layer and the insulating layer to form a first slit-type contact hole exposing a partial portion of the well region; performing an ion-implantation to the partial portion of the well region to form a plug; and filling up a conductive material into the first contact hole.

The forming a second contact may include: etching the intervening insulation layer to form a second contact hole exposing a partial portion of the second electrode; performing an ion-implantation to the second electrode; and filling up a conductive material into the second contact hole. The method further comprises: forming metal wires connected the first and the second contacts over the intervening insulation layer.

According to an embodiment of the present invention, a semiconductor device formed on a substrate including a silicon-on-insulator structure may include a capacitor and a transistor wherein one electrode of the capacitor is located at the same level with a source and a drain of the transistor and the other electrode of the capacitor is located at lower level than the source and the drain of the transistor.

The one electrode of the capacitor may be formed by an ion-implantation to partial portion of a silicon layer on an insulator in the substrate and the other electrode of the capacitor may be a well region of another silicon layer under the insulator in the substrate.

The semiconductor device further may include a contact, connected to the other electrode of the capacitor through the insulator of the substrate, for coupling the capacitor to a wire. The semiconductor device further may include a plug, formed in the well region of another silicon layer, for reducing a resistance of a junction between the other electrode and the contact, wherein the plug has higher dopant ion-concentration than the well region.

According to an embodiment of the present invention, a method for manufacturing a semiconductor device may include: performing ion-implantation to active regions in a substrate including a silicon-on-insulator structure to thereby form one electrode of a capacitor and a source and a drain of a transistor.

The method further may include: forming a gate on a center of the active region in a transistor region; and forming a contact coupled to the other electrode of the capacitor through the insulator of the substrate, wherein the other electrode of the capacitor is a well region of a silicon layer under the insulator.

### BRIEF DESCRIPTION OF THE DRAWINGS

FIGS. 1a to 1b are cross-sectional diagrams showing a semiconductor device according to an embodiment of the present invention.

FIGS. 2a to 2g are cross-sectional diagrams illustrating a method for manufacturing the semiconductor device of FIG. 1.

### DESCRIPTION OF EMBODIMENTS

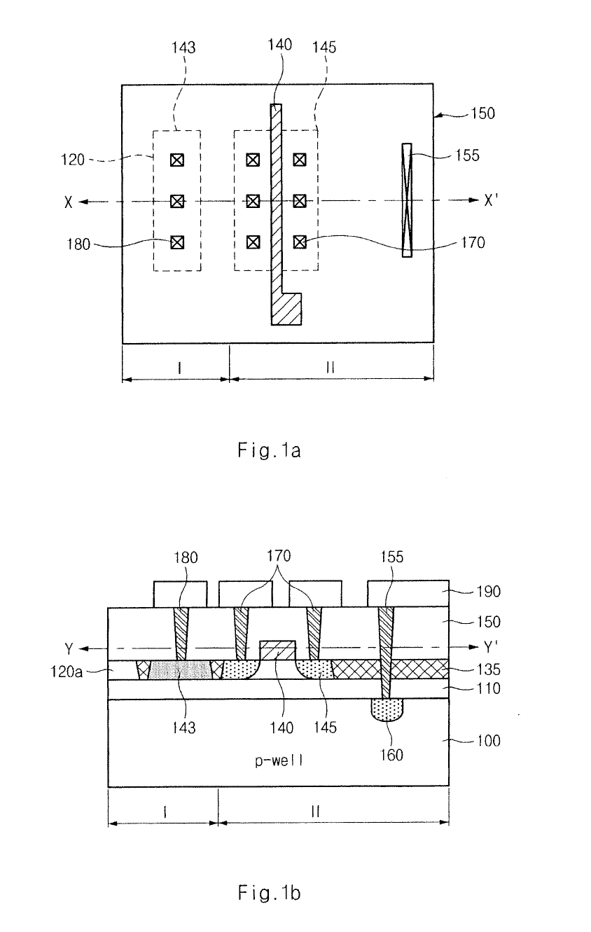

FIGS. 1a to 1b are cross-sectional diagrams showing a semiconductor device according to an embodiment of the present invention. FIG. 1a shows a layout of a semiconductor device formed over a SOI wafer taken along Y-Y′ of FIG. 1b. FIG. 1b shows a cross-sectional diagram taken along X-X of FIG. 1a.

Referring to FIG. 1b, a capacitor region I and a transistor region II are defined over a SOI wafer including a first silicon layer 100, a buried oxide layer 110 and a second silicon layer (not shown).

Each active region 120a is defined in the capacitor region I and the transistor region II through a device isolating film 135 where the second silicon layer is removed. A gate electrode 140 is formed over the active region 120a of the transistor region II and located in the middle of the active region 120a.

In the semiconductor device, n+ impurity ions are implanted into the active region 120a of the capacitor region I, thereby obtaining a n+ conductive junction region 143 which is used a top electrode of a capacitor. The n+ impurity ions are implanted into both sides of the gate electrode 140, thereby obtaining source/drain regions 145 of a transistor in the active region 120a of the transistor region II.

The entire p-well region formed in the first silicon layer 100 is used as a bottom electrode of the capacitor. A p+ conductive junction region 160 formed in the p-well region is a plug for lowering a junction resistance with a contact.

The semiconductor device further includes a wire 190 for connecting the transistor and the capacitor to other devices and circuits, a first contact 155 for connecting the wire 190 with the p+ conductive junction region which is a bottom electrode of the capacitor, a third contact 180 for connecting the wire to the n+ conductive junction region 143 which is a top electrode of the capacitor, and a second contact 170 for connecting the wire 190 to the source/drain regions of the transistor.

The first contact 155 has a slit type in order to lower a junction resistance while improving integration of the semiconductor device.

Referring to FIG. 1a, the first contact 155 connected to the bottom electrode of the capacitor is disposed remote from the third contact 180 connected to the top electrode of the capacitor. However, since it corresponds to one embodiment, the first contact 155 may be formed adjacent to the third contact 180. The first contact 155 may be disposed over the p-well region of the first silicon layer 100 which is the bottom electrode of the capacitor.

Although FIGS. 1a to 1b are described based on an embodiment wherein the capacitor is located around NMOS, the same layout may be formed where the capacitor is located around PMOS.

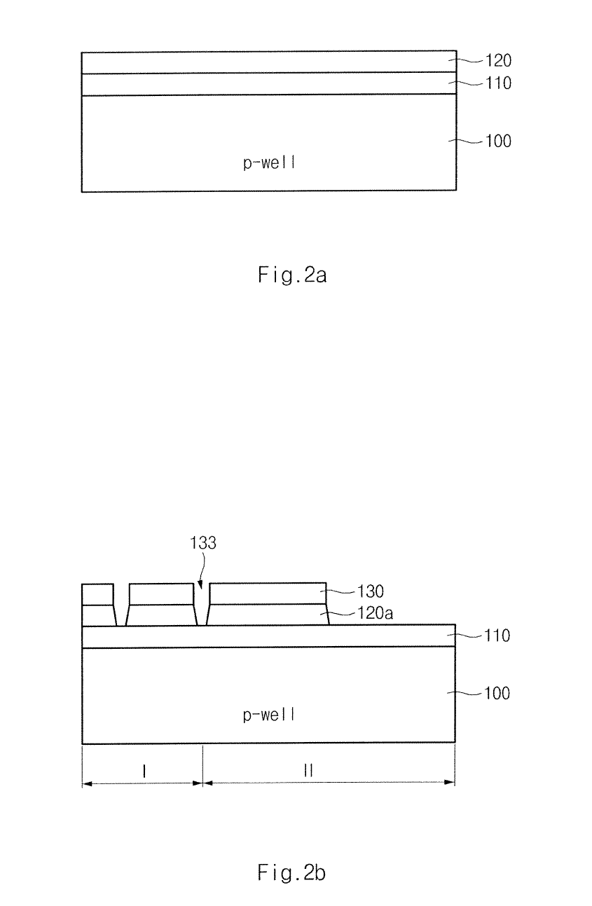

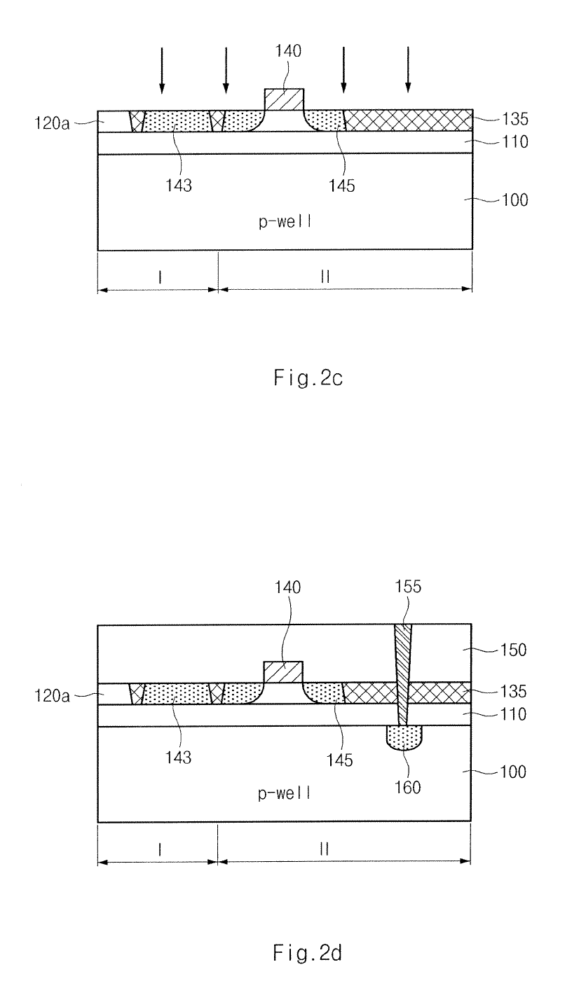

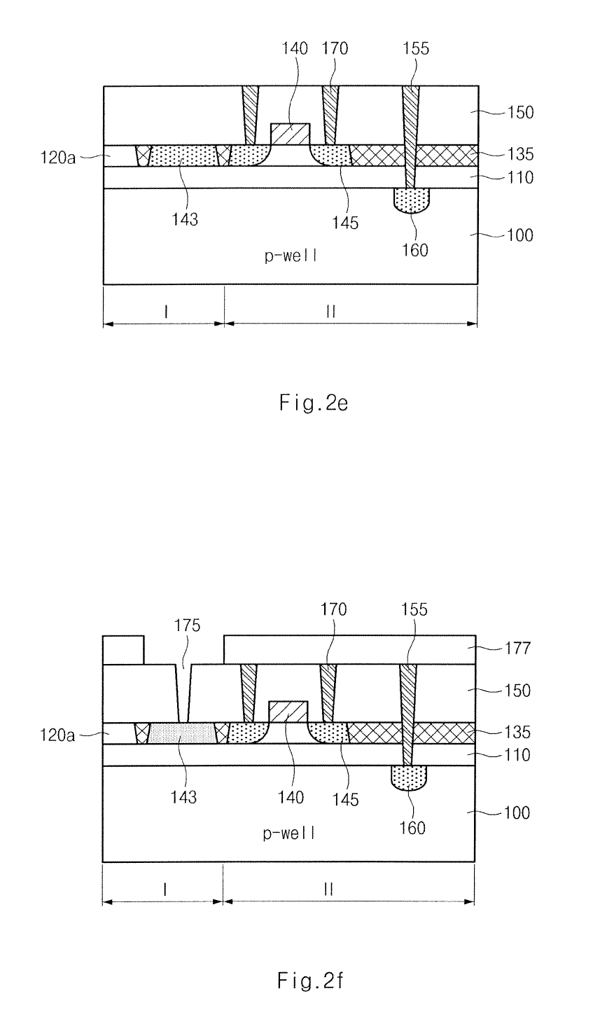

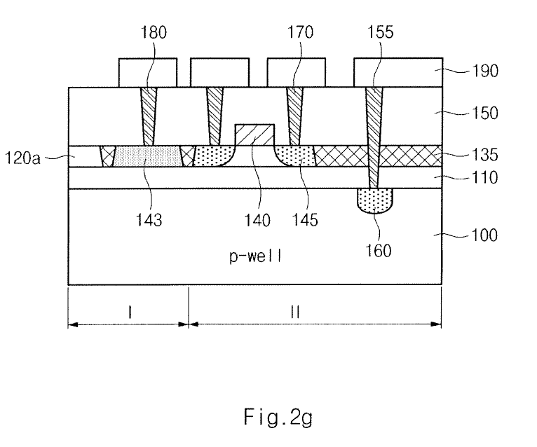

FIGS. 2a to 2g are cross-sectional diagrams illustrating a method for manufacturing the semiconductor device of FIGS. 1a to 1b.

Referring to FIG. 2a, a buried oxide layer 110, which is an insulating layer, is formed over the first silicon layer 100 of the p-well region. A second silicon layer 120 is formed over the buried oxide layer 110 to obtain a SOI wafer.

Referring to FIG. 2b, a first photoresist pattern 130 that defines the active region 120a is formed over the second silicon layer 120. The second silicon layer 120 is etched with the first photoresist pattern 130 as a mask to form a device isolating trench 133.

In a region defined as the capacitor region I, the top electrode of the capacitor is formed. In a region defined as the transistor region II, the transistor is formed.

Referring to FIG. 2c, after the device isolating trench 133 is formed, the first photoresist pattern 130 is removed.

The device isolating trench 133 is buried to form a device isolating film 135 that defines the active region 120a.

A gate electrode 140 is formed over the active region 120a of the second silicon layer 120 of the transistor region II. The n+ impurity ions are implanted with the gate electrode 140 as a barrier to form source/drain regions 145 at both sides of the gate electrode 140. During the implant process for forming the source/drain regions 145, the implant process is performed simultaneously on the active region 120a of the capacitor region I to form a n+ conductive junction region 143.

The gate electrode 140 has a deposition structure including a gate insulating film, a gate conductive layer and a gate hard mask layer.

Referring to FIG. 2d, an interlayer insulating film 150 is formed over the resulting structure including the gate electrode 140.

An interlayer insulating film 150, the device isolating film 135 and the buried oxide layer 110 are etched to form a first contact hole (not shown) exposing the first silicon layer 100 in the transistor region II. The first contact hole (not shown) has a slit type.

The p+ impurity ions are implanted into the first silicon layer 100 exposed by the first contact hole (not shown) to form a p+ conductive junction region 160. The p+ conductive junction region 160 is a plug obtained by implanting impurities of high concentration in order to reduce a contact resistance of the first silicon layer 100 and metal wires.

The first contact hole (not shown) is buried to form a first contact 155.

The first contact 155 is formed over the p-well region of the first silicon layer 100 used as a bottom electrode of the capacitor, whose location may be changed depending on design of the semiconductor device.

Referring to FIG. 2e, the interlayer insulating film 150 formed over the source/drain regions 145 located at both sides of the gate electrode 140 is etched to form a second contact hole (not shown) exposing the source/drain regions 145. For a stable operation of the transistor, the second contact hole (not shown) is separated from the gate electrode 140.

The second contact hole (not shown) is buried to form a second contact 170 connected with the source/drain regions 145.

Referring to FIG. 2f, the interlayer insulating film 150 of the capacitor region I is etched to form a third contact hole 175 exposing the active region 120, that is, the n+ conductive junction region 143 which is a top electrode of the capacitor.

A second photoresist pattern 177 is formed which exposes the third contact hole 175 and a part of the interlayer insulating film 150 adjacent to the third contact hole 175.

An additional implant process is performed with the second photoresist pattern 177 as a barrier to increase the concentration of n+ impurity ions of the n+ conductive junction region 143 used as a top electrode of the capacitor, thereby increasing a concentration difference from the n+ impurity ion concentration of the source/drain regions 145 of the transistor.

Referring to FIG. 2g, the third contact hole 175 is buried to form a third contact 180 connected to the top electrode of the capacitor.

A metal layer (not shown) is formed over the interlayer insulating film 150 including the first contact 155, the second contact 170 and the third contact 180.

The metal layer (not shown) is patterned to form metal wires 190 connected to the first contact 155, the second contact 170 and the third contact 180, respectively.

In an embodiment of the present invention, when a semiconductor device is manufactured in a SOI wafer, a conventional process and structure are changed. In other words, a well of a silicon layer located in a bottom of a buried oxide layer may be used as a bottom electrode of a capacitor, and the buried oxide layer may be etched to form a contact connected to the well. Furthermore, impurities of high concentration may be implanted into a second silicon layer disposed in the top of the buried oxide layer, which may be used as a top electrode of the capacitor. As a result, a capacitor using a SOI wafer structure can be obtained.

The buried oxide layer which may be an insulating layer included in the SOI wafer is generally formed to be thicker than a common gate oxide film. When a high voltage is applied to one side of the capacitor, a stable operation can be secured rather than a conventional MOS capacitor. Although the transistor is exemplified with the capacitor in the embodiment of FIGS. 1a and 1b, the transistor may be operated as a MOS capacitor when the two second contacts 170 are connected to the source/drain regions 145 of the transistor.

As described above, according to an embodiment of the present invention, in a process for fabricating a SOI device, a contact connected to a well of a lower silicon layer disposed in a bottom of a buried oxide layer may be formed and used as a bottom electrode of a capacitor, and impurity ions of high concentration may be implanted into an upper silicon layer to form a contact which is used as a top electrode of the capacitor. As a result, the capacitor can be stably operated even in a high voltage.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device formed on a silicon-on-insulator structure including first and second silicon layers and a insulating layer buried between the first and the second silicon layers, comprising a capacitor including a first electrode formed in a doped region of the first silicon layer and a second electrode formed in a well region of the second silicon layer.

2. The semiconductor device according to claim 1, further comprising a transistor including a gate formed on an active region of the first silicon layer and a source and a drain formed at sides of the gate in the active region.

3. The semiconductor device according to claim 2, further comprising an isolation layer, formed in a trench where the first silicon layer is removed, for defining the active region.

4. The semiconductor device according to claim 1, further comprising:
a first contact for coupling the first electrode to a first wire; and
a second contact having a slit-type shape for coupling the second electrode to a second wire.

5. The semiconductor device according to claim 4, further comprising a plug, formed in the well region, for reducing a contact resistance between the second electrode and the second contact.

6. The semiconductor device according to claim 1, wherein the well region is P type ion-doped, the plug is P+ type ion-doped, and the doped region is N+ type ion-doped.

7. The semiconductor device according to claim 1, wherein the well region is N type ion-doped, the plug is N+ type ion-doped, and the doped region is P+ type ion-doped.

8. A method for manufacturing a semiconductor device, comprising:
preparing a wafer having a silicon-on-insulator structure including first and second silicon layers and a insulating layer buried between the first and the second silicon layers, wherein the second silicon layer includes a well region as a first electrode of a capacitor; and
performing ion-implantation to the first silicon layer to form a second electrode of the capacitor.

9. The method according to claim 8, further comprising forming an isolation layer for defining the active region in a trench where the first silicon layer is removed.

10. The method according to claim 9, further comprising:
forming a gate on the active region; and
performing an ion-implantation to form a drain and a source at sides of the gate in the active region.

11. The method according to claim 8, further comprising:
forming an intervening insulation layer over the first silicon layer;
forming a first contact on the well region of the second silicon layer through the intervening insulation layer and the insulating layer; and
forming a second contact on the second electrode through the intervening insulation layer.

12. The method according to claim 11, wherein the forming a first contact includes:
etching the intervening insulation layer and the insulating layer to form a first slit-type contact hole exposing a partial portion of the well region;
performing an ion-implantation to the partial portion of the well region to form a plug; and
filling up a conductive material into the first contact hole.

13. The method according to claim 11, wherein the forming a second contact includes:
etching the intervening insulation layer to form a second contact hole exposing a partial portion of the second electrode;
performing an ion-implantation to the second electrode; and
filling up a conductive material into the second contact hole.

14. The method according to claim 11, further comprising:
forming metal wires connected the first and the second contacts over the intervening insulation layer.

15. A semiconductor device formed on a substrate including a silicon-on-insulator structure, comprising a capacitor and a transistor wherein a first electrode of the capacitor is located at a same level with a source and a drain of the transistor and a second electrode of the capacitor is located at a lower level than the source and the drain of the transistor.

16. The semiconductor device according to claim 15, wherein the first electrode of the capacitor comprises an ion-implanted partial portion of a first silicon layer on an insulator in the substrate and the second electrode of the capacitor is a well region of second silicon layer under the insulator in the substrate.

17. The semiconductor device according to claim 16, further comprising a contact connected to the second electrode of the capacitor through the insulator of the substrate for coupling the capacitor to a wire.

18. The semiconductor device according to claim 17, further comprising a plug formed in the well region of second silicon layer for reducing a resistance of a junction between the second electrode and the contact, wherein the plug has higher dopant ion-concentration than the well region.

19. A method for manufacturing a semiconductor device, comprising:
performing ion-implantation to active regions in a substrate including a silicon-on-insulator structure to thereby form a first electrode of a capacitor and a source and a drain of a transistor.

20. The method according to claim 19, further comprising:
forming a gate on a center of the active region in a transistor region; and
forming a contact coupled to a second electrode of the capacitor through the insulator of the substrate, wherein the second electrode of the capacitor is disposed in a well region of a silicon layer under the insulator.
